(19) United States
(12) Patent Application Publication
(10) Pub. No.: US 2026/0256004 A1
(43) Pub. Date: Aug. 27, 2026

(54) FLIP-CHIP BONDING WITH TILT FEEDBACK

(71) Applicant: IQM FINLAND OY, Espoo (FI)

(72) Inventors: Vladimir MILCHAKOV, Espoo (FI); Eelis TAKALA, Espoo (FI); Máté JENEI, Espoo (FI)

(21) Appl. No.: 19/140,162

(22) PCT Filed: Dec. 21, 2022
(86) PCT No.: PCT/FI2022/050862

§ 371 Date: Jun. 17, 2025

(51) Int. Cl. H10W 72/00; H10P 74/20

(52) U.S. Cl. CPC H10W 72/07223; H10P 74/203; H10W 72/07178

(57) ABSTRACT

A method for a flip-chip bonding system, where a chip is pressed toward a mounting surface by applying pressure on the chip. A tilt angle is measured between the chip and the mounting surface while the chip is being pressed toward the mounting surface. If the measured tilt angle differs from a predetermined threshold, the tilt angle is adjusted by adjusting the pressure distribution while the chip is being pressed toward the mounting surface.

### FIELD OF THE DISCLOSURE

The present disclosure relates to electronic component bonding, and more particularly to flip-chip bonding. The present disclosure further concerns process control during flip-chip bonding.

### BACKGROUND OF THE DISCLOSURE

Flip-chip bonding allows reliable electrical connections to be formed between a chip and a mounting surface. Contact pads are formed on one surface of a chip when it is manufactured. These contact pads facilitate electrical access to the chip. Corresponding contact pads are formed on the surface where the chip will be mounted. When the chip is mounted, the contact pads on the chip are electrically connected to contact pads on the surface by placing electrically conductive bumps between each pair of contact pads. The bumps are then allowed to deform while the chip is being pressed toward the surface. Additional adhesive material may be added in between the chip and the surface after the bumps have solidified.

A general problem in flip-chip bonding is that if the deformation process did not proceed evenly at each bump, the chip may become slightly tilted with respect to the surface where it is mounted. This can lead to significant errors in circuits which contain orientation-sensitive elements. It is possible to check the tilt angle between a chip and a mounting surface after the flip-chip bonding process has been completed, for example through electron microscopy of optical profilometric measurements. However, if the tilt angle differs from the desired value, the sample will often have to be discarded. Possible corrections can only be implemented when the next sample is bonded, and a lot of trial-and-error experimentation may be needed before the factors which caused the tilt have been identified.

### BRIEF DESCRIPTION OF THE DISCLOSURE

An object of the present disclosure is to provide a method and an apparatus which overcome the above problems.

The object of the disclosure is achieved by a method and an arrangement which are characterized by what is stated in the independent claims. The preferred embodiments of the disclosure are disclosed in the dependent claims.

The disclosure is based on the idea of measuring possible tilting already during the flip-chip bonding process. An immediate adjustment can then be made, and the tilt can be eliminated before the flip-chip bonding process is completed. An advantage of the method and arrangement of the disclosure is that no samples have to be discarded because of tilting errors.

### BRIEF DESCRIPTION OF THE DRAWINGS

In the following the disclosure will be described in greater detail by means of preferred embodiments with reference to the accompanying drawings, in which

FIG. 1 illustrates a method.

FIG. 2 illustrates a flip-chip bonding apparatus.

FIGS. 3a-3c illustrate an interferometer embodiment.

FIGS. 4a-4b illustrate a resonator embodiment.

FIGS. 5a-5b illustrate a diffraction embodiment.

FIGS. 6a-6b illustrate a solder bump embodiment.

FIG. 7 illustrates a reflection embodiment.

### DETAILED DESCRIPTION OF THE DISCLOSURE

This disclosure describes a method for attaching a chip on a mounting surface in a flip-chip bonding system. The method comprises pressing the chip toward the mounting surface by applying pressure on the chip. The pressure has a spatial pressure distribution across the surface of the chip. The method also comprises measuring a tilt angle between the chip and the mounting surface while the chip is being pressed toward the mounting surface. The method also comprises comparing the measured tilt angle to a predetermined threshold and, if the measured tilt angle differs from the threshold, adjusting the tilt angle by adjusting the pressure distribution while the chip is being pressed toward the mounting surface.

If the measured tilt angle may for example exceeds the threshold, the step of adjusting the pressure distribution may reduce the tilt angle. Alternatively, if the measured tilt angle lies below the threshold, the step of adjusting the pressure distribution may increase the tilt angle.

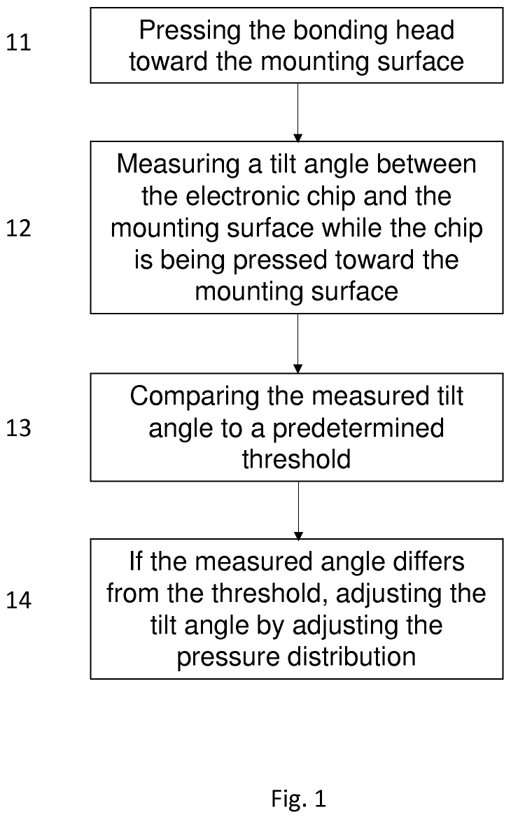

The method has been illustrated in FIG. 1. Reference numbers 11-14 indicate the various steps that are included in the method.

The method may for example comprise grasping the chip with a movable bonding head and positioning the bonding head above the mounting surface so that the chip is aligned with the mounting surface. The step of applying pressure on the chip may comprise pressing the bonding head toward the mounting surface. The step of adjusting the tilt angle by adjusting the pressure distribution may comprise changing the position of the bonding head while the bonding head is being pressed toward the mounting surface. This option can be combined with any other embodiment presented in this disclosure.

Alternatively, the bonding head may comprise a force actuator which can change the pressure distribution even without any movement in the bonding head. The force actuator may for example comprise means for generating an electric or magnetic force between the chip and the mounting surface. This option can also be combined with any other embodiment presented in this disclosure. Other means for changing the pressure distribution can also be used in any embodiment.

Furthermore, any method described in this disclosure for changing the pressure distribution may optionally be complemented with an adjustment where the local temperature is changed close to one edge of the chip. A change in temperature influences the shear-stress profile of the solder bumps. Increasing the temperature at a first edge allows inelastic formation to occur in nearby solder bumps near the first edge at lower stress than at solder bumps which are near the other edges of the chip. This can be used to facilitate an easier change in the tilt angle. Local temperature changes may in some cases be used as an independent way to change the tilt angle, without any changes in the pressure distribution.

A corresponding flip-chip bonding apparatus may comprise an actuator coupled to a chip and a control unit coupled to the actuator. The control unit is configured to control the actuator so that it presses the chip toward a mounting surface. The pressure applied by the actuator has a spatial pressure distribution across the surface of the chip. The apparatus also comprises a measurement arrangement coupled to the control unit. The measurement arrangement is configured to measure a tilt angle between the chip and the mounting surface when the actuator presses the chip toward the mounting surface. The control unit is configured to adjust the tilt of the chip by adjusting the pressure distribution based on the measured tilt angle.

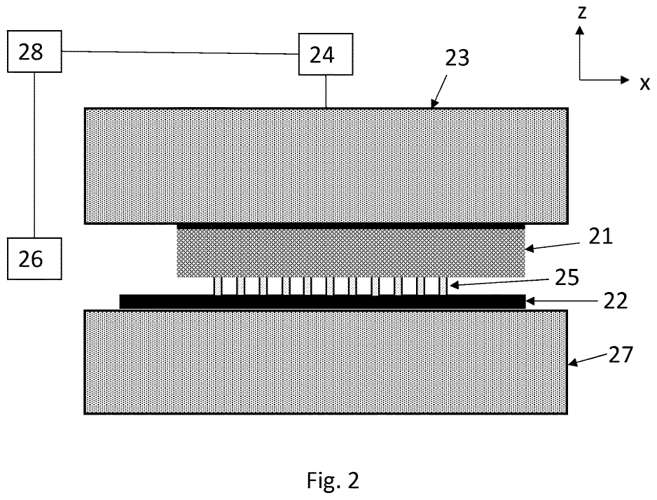

FIG. 2 illustrates a flip-chip bonding apparatus which comprises a fixed support 27 for holding a mounting surface 22, and a movable bonding head 23 for grasping a chip 21. The chip 21 will be attached in the flip-chip process to mounting surface 22 with solder bumps 25. The apparatus also comprises an actuator 24 coupled to the chip 21 via the bonding head 23 and a control unit 28 coupled to the actuator. The control unit 28 is configured to move the bonding head 23 by controlling the actuator 24. The apparatus also comprises a measurement arrangement 26 coupled to the control unit 28, and the measurement arrangement 28 is configured to measure a tilt angle between (i) the chip 21 grasped by the bonding head 23 and (ii) the mounting surface 22 held on the fixed support 27 when the actuator 24 presses the bonding head 23 toward the fixed support 27. The control unit 28 is configured to change the pressure distribution based on the measured tilt angle by adjusting the tilt of the bonding head 23.

In other words, the measurement arrangement provides immediate feedback to the control unit concerning the current angle between the chip and the mounting surface while the bonding process is under way and the chip is being pressed toward the mounting surface. The control unit can be programmed to automatically adjust the positioning of the bonding head in order to change the angle. This recursive process of measurement and adjustment can ensure that the chip and the mounting surface are parallel to each other when the bonding is concluded and the position of the chip in relation to the mounting surface becomes fixed. Various measurement arrangements can be used to achieve this goal.

The flip-chip bonding apparatus may comprise one or more actuators which exerts and electric or magnetic force on the chip. These actuators may for example be Coulombic or Johnsen-Rabek electrostatic actuators. The actuators may comprise multiple electrodes spread across the surface area of the chip. By altering the voltages applied to these electrodes, the pressure distribution may be changed. Electrostatic actuators may be implemented together with other means for altering the pressure distribution (for example force actuation occurring via the bonding head), or as a stand-alone solution.

The mounting surface may for example be the top surface of a circuit board or an electronic component, or any other surface to which the chip can be physically attached and electrically connected. The mounting surface may define an xy-plane and a z-axis which is perpendicular to the xy-plane.

The circuit board or component which contains the mounting surface may be attached to a fixed structure during the flip-chip bonding process. The fixed structure may for example be called a bonding table. The mounting surface may remain stationary throughout the flip-chip bonding process.

The bonding head may be any kind of arrangement where the chip can be temporarily attached during the flip-chip bonding process. The act of temporarily attaching the chip to the bonding head will in this disclosure be called “grasping” the chip with the bonding head. The temporary attachment of the chip to the bonding head may for example be achieved with electrical or magnetic force, with the help of adhesives and/or vacuum suction.

The bonding head is movable in relation to the fixed support. The bonding head may for example be placed at the end of a robotic bonding arm which comprises a part of the actuator 24. The control unit may adjust the position of the bonding arm and the bonding head by controlling the actuator. The movements and adjustments produced by the actuator 24 may include horizontal movement parallel to the plane defined by the mounting surface and vertical movement in the direction which is perpendicular to that plane. The former adjustment allows the chip to be aligned with the intended attachment region on the mounting surface, and the latter adjustment allows the chip to be pressed against the mounting surface. The actuator may comprise different parts for generating downward pressure and horizontal movement.

The adjustments which can be made to the position of the bonding head may also include rotation of the bonding head in a plane which is parallel to the plane defined by the mounting surface. The adjustments may also include rotation of the bonding head about an axis which is parallel to the plane defined by the mounting surface. The latter rotation may for example be achieved by tilting the bonding arm, and it may be used to change the angle between the bottom surface of the chip and the mounting surface.

The flip-chip bonding process comprises a step where the bonding head brings the chip into close proximity with the mounting surface presses the chip against the mounting surface. Many different bonding methods are possible. The chip may for example comprise a bottom surface with one or more first contact pads, and the mounting surface may comprise one or more second contact pads. The one or more first contact pads may be aligned with the one or more second contact pads when the bonding head is positioned above the mounting surface. The method may comprise placing electrically conductive solder bumps on the one or more first contact pads and/or on the one or more second contact pads before pressing the bonding head toward the mounting surface. In any embodiment presented in this disclosure, the bumps may for example be made of indium.

By pressing the chip toward the mounting surface, the chip can be firmly attached to the mounting surface with the solder bumps, and the first contact pads can also be electrically connected to the second contact pads with the solder bumps. The pressing and tilt adjustment may be performed at room temperature or at cryogenic temperatures, for example at a temperature below −100° C. The open space between the chip and mounting surface may be filled with an underfill material after they have been attached to each other. Measuring the tilt angle may comprise measuring the gap between the chip and the mounting surface in two or more measurement locations. If the gap is measured only in two points on the mounting surface, then the tilt angle can be determined only along the line which passes through these points. If the gap is measured on three or more points on the mounting surface, and if these three or more points do not all lie on the same line on the mounting surface, then the tilt angle in any direction can be determined.

The measurement arrangement may comprise a device for measuring the gap between the chip and the mounting surface in two or more measurement locations.

In one embodiment where the chip is grasped by a movable bonding head, the bonding head may comprise a first transparent section in each of the two or more measurement locations, through which the chip can be illuminated. The bonding head may further comprise a second transparent section in each of the two or more measurement locations, through which the mounting surface can be illuminated. Measuring the gap between the surface of the chip and the mounting surface in each of the two or more measurement locations may comprise simultaneously illuminating the chip through the first transparent section and the mounting surface through the second transparent section and measuring the interferometry pattern between electromagnetic radiation reflected through the first transparent section from the chip and electromagnetic radiation reflected through the second transparent section from the mounting surface.

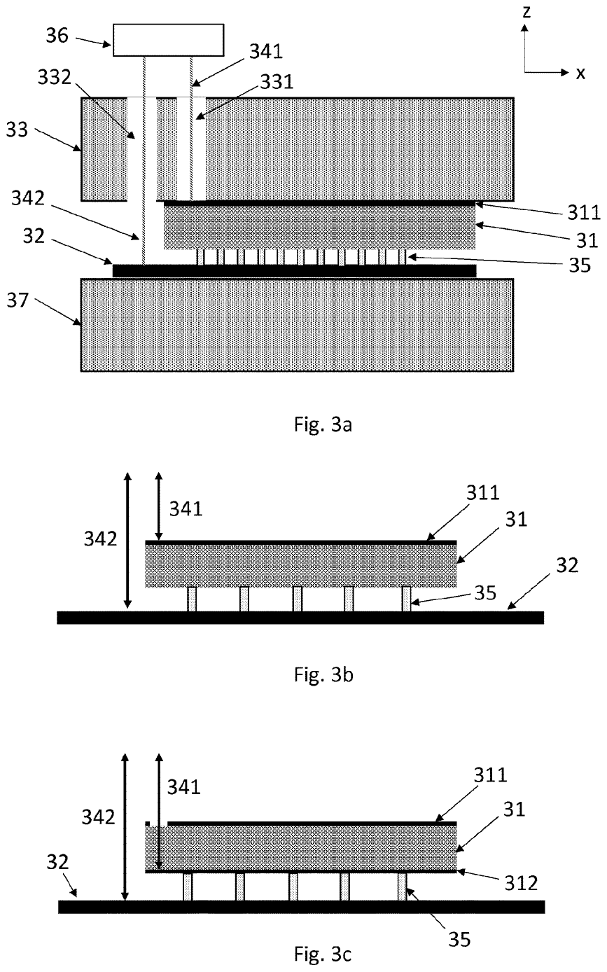

FIG. 3a illustrates a device which comprises a bonding head 33 which has grasped a chip 31. The chip 31 is aligned with a mounting surface 32. The mounting surface has been attached to a fixed structure 37. Solder bumps 35 have been illustrated simply as lines between the chip 31 and the mounting surface 32. Contact pads are not illustrated. The bonding head 33 comprises a first transparent section 331 and a second transparent section 332. The transparent sections may be openings in the bonding head. Alternatively, they could be sections made of glass or some other material which is transparent to the electromagnetic radiation 341/342 which is used for illumination in this embodiment. The transparent sections may extend through the bonding head in the z-direction. Only one first transparent section and one second transparent section in one measurement location is illustrated, but the device may comprise several first and second transparent sections when gap measurements are performed in more than one measurement location. Each first transparent section 331 is located in a part of the bonding head 33 which is aligned with the chip 31 in the z-direction. Each second transparent section 332 is located in a part of the bonding head 33 which is aligned with the mounting surface 32, but not with the chip 31, in the z-direction.

The measurement arrangement comprises an interferometer 36 which also acts as a source of electromagnetic radiation and emits electromagnetic radiation 341/342 through the first transparent section 331 toward the chip 31 and through the second transparent section 332 toward the mounting surface 32. The radiation source and interferometer could alternatively be two different devices. The interferometer also receives the radiation 341/342 after it has been reflected back upward from the chip or from the mounting surface. The electromagnetic radiation 341/342 may for example be visible radiation, UV radiation or infrared radiation.

The electromagnetic radiation 341 which reaches the chip 31 through the first transparent section 331 may be reflected back to the first transparent section from the top surface of the chip 31 which is closer to the bonding head 33. The chip may optionally comprise a top reflective layer 311 on its top surface which reflects the incoming radiation 341 back towards the interferometer 36. The incoming electromagnetic radiation 342 may similarly be reflected back toward the interferometer from the mounting surface 32. This is illustrated in FIG. 3b. The gap between the bottom surface of the chip 31 and the mounting surface 32 at this measurement location can be precisely determined by measuring the interference of light beams 341 and 342 in the interferometer.

The electromagnetic radiation 341 which reaches the chip 31 through the first transparent section 33 may alternatively be reflected back to the first transparent section 331 from the bottom surface of the chip 31, which is further away from the bonding head. The chip may for example be a silicon chip, which is transparent to infrared radiation, or a sapphire chip which is transparent to visible radiation. In this case the bottom surface of the chip 31 may comprise an optional bottom reflective layer 312, as FIG. 3c illustrates. Any layer which has been deposited on the top side, such as 311 in FIG. 3c, may comprise an opening where the radiation 341 can enter the chip 31 without being reflected from the top surface.

In another embodiment, the chip or the mounting surface may comprise a superconducting circuit, and the superconducting circuit may comprise a co-planar waveguide resonator in each of the two or more measurement locations. Measuring the gap between the surface of the chip and the mounting surface in each of the two or more measurement locations may comprise measuring the resonance frequency of the co-planar waveguide resonator in each of the two or more measurement locations.

In a corresponding apparatus, the chip and/or the mounting surface comprises a superconducting circuit and the superconducting circuit comprises a co-planar waveguide resonator in each of the two or more measurement locations. The measurement arrangement comprises a resonance measurement device configured to measure the resonance frequency of each co-planar waveguide resonator.

A superconducting circuit on a chip or on a mounting surface may be used for measuring a tilt angle between the chip and the mounting surface while the chip is being pressed toward the mounting surface in a flip-chip bonding process. The superconducting circuit may comprise a co-planar waveguide resonator in two or more measurement locations where the gap between the chip and the mounting surface is measured. The use may comprise measuring the resonance frequency of each co-planar waveguide resonator.

The flip-chip bonding system may be brought to cryogenic temperatures where at least some electrical elements on the mounting surface and/or on the chip exhibit superconductivity. The superconducting circuit may include a co-planar waveguide resonator as one such element. Other circuitry on the mounting surface and/or on the chip may comprise a signal generator and transmission lines which can transmit an electrical signal from the signal generator to the co-planar waveguide resonator. The electrical signal may bring the resonator into a state of electrical resonance when its frequency is chosen in a suitable manner.

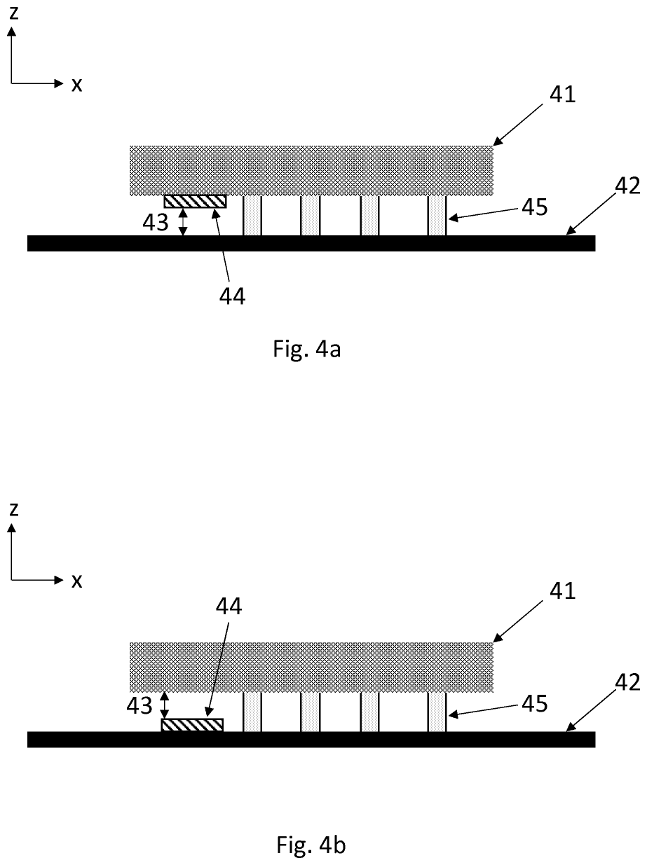

FIG. 4a illustrates a chip 41, a mounting surface 42 and solder bumps 45 which attach and connect the chip 41 to the mounting surface 42. The bonding head and the fixed support have been omitted from this figure. A co-planar waveguide resonator 44 is on the bottom side of the chip 41. The thickness of the resonator in relation to the thickness of the chip has been greatly exaggerated. The resonance frequency of this resonator can be determined with standard measurements. The resonance frequency will depend on electrical surroundings of the waveguide resonator. It is strongly influenced by the proximity of the mounting surface 42. The gap 43 between the resonator 44 and the mounting surface 42 can therefore be determined by measuring the resonance frequency. FIG. 4b illustrates an alternative arrangement where the co-planar waveguide resonator 44 is located on the mounting surface 42. The measurement principle is the same.

The surface which is adjacent to the resonator-i.e. the region of the mounting surface 42 which lies directly below the resonator 44 in FIG. 4a, or the region of the chip 41 which lies directly above the resonator 44 in FIG. 4b, may optionally be coated with a superconducting material. It may alternatively be insulating.

Co-planar waveguide resonators could alternatively be arranged on both the chip and the mounting surface at each measurement location. The waveguide resonator on the chip may be aligned with the resonator on the mounting surface at each measurement location. This option has not been separately illustrated.

In another embodiment, measuring the gap between the surface of the chip and the mounting surface in each of the two or more measurement locations may comprise illuminating said gap at each of the two or more measurement locations with a light source which emits electromagnetic radiation into the gap so that said electromagnetic radiation is diffracted at the gap, and measuring the gap further comprises measuring the diffracted electromagnetic radiation with a radiation detector.

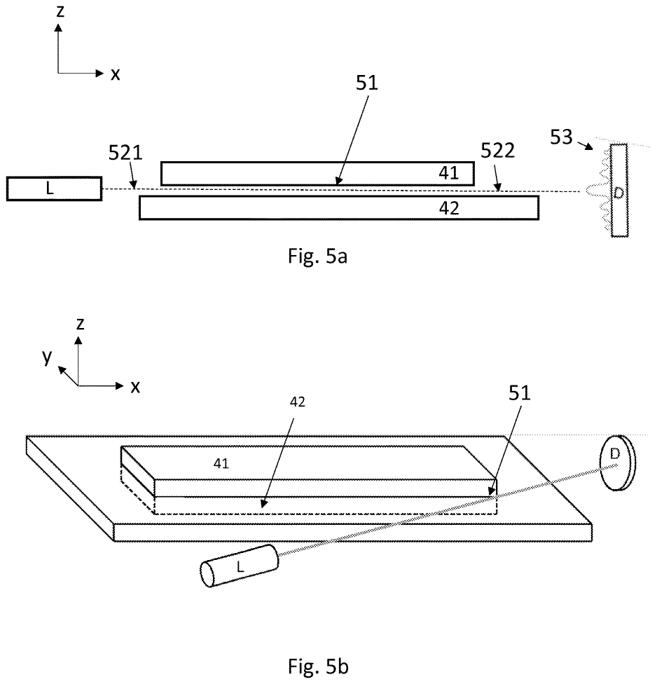

The wavelength of the electromagnetic radiation may in this case lie in the visible or infrared range. The wavelength may be of the same order of magnitude as the expected gap at the two or more measurement locations. The wavelength may for example be in the range 400 nm-1 mm, or in the range 800 nm-1 mm, or in the range 800 nm-3000 nm. FIG. 5a illustrates schematically a flip-chip bonding system where the gap between a chip 41 and a mounting surface 42 is measured at one measurement location 51.

A light source L emits a radiation beam 521 toward the gap between the chip 41 and the mounting surface 42 at the measurement location 51. The radiation beam may be parallel to the mounting surface. If the selected wavelength of this electromagnetic radiation is suitable, and if the gap is sufficiently narrow, the incoming electromagnetic radiation 521 will be diffracted at the gap, so that diffracted electromagnetic radiation 522 can be detected with a radiation detector D. The radiation detector may comprise multiple pixels, so that it can resolve the spatial intensity variation, illustrated as diffraction pattern 53 in FIG. 5a, of the diffracted electromagnetic radiation 522. The height of the gap at the measurement location 51 can be determined by analyzing the pattern 53. The same measurement can be repeated at multiple measurement locations.

The two or more measurement locations may be located at corresponding two or more corners of the chip 41. This is illustrated in FIG. 5b. By aiming the light beam close to a corner, the measurement location can be pinpointed in the xy-plane. The tilt of the chip in relation to the mounting surface can then be calculated after the measurement has been conducted at two or more corners of the chip.

The tilt angle can alternatively be measured also by indirect means, without directly measuring gap between the chip and the mounting surface.

In one embodiment, the chip comprises a bottom surface with one or more first contact pads, and the mounting surface comprises one or more second contact pads, and the one or more first contact pads are aligned with the one or more second contact pads when the bonding head is positioned above the mounting surface, and the method comprises placing electrically conductive solder bumps on the one or more first contact pads and/or on the one or more second contact pads before pressing the bonding head toward the mounting surface, and measuring the tilt angle between the surface of the chip and the surface of the mounting surface comprises measuring the resistance between at least one first contact pad and at least second contact pad which are connected to each other by at least one solder bump.

In a corresponding device, the chip comprises one or more first contact pads, and the mounting surface comprises one or more second contact pads, and the one or more first contact pads are connected to the one or more second contact pads with electrically conductive solder bumps, and the measurement arrangement comprises an electrical resistance measurement device configured to measure the resistance between at least one of the one or more first contact pads and at least one of the one or more second contact pads.

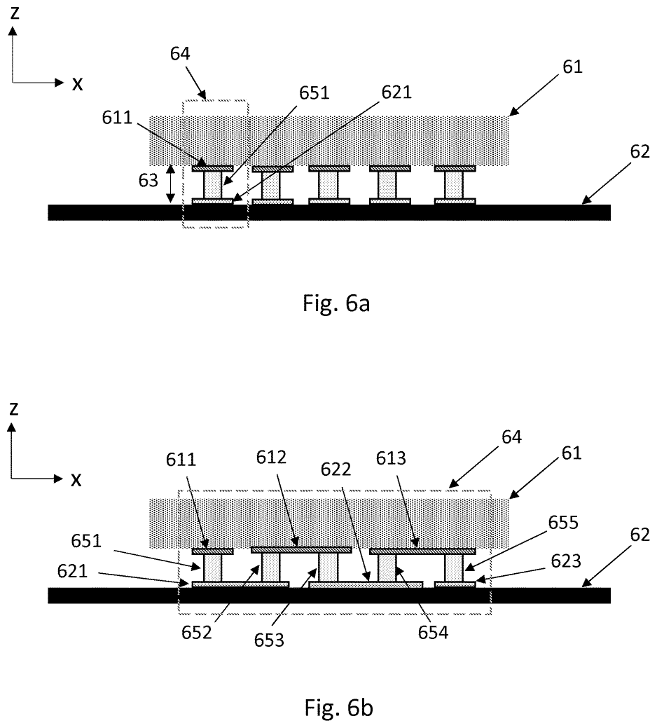

FIG. 6a illustrates schematically a flip-chip bonding system device where a chip 61 is bonded to a mounting surface 62. The bonding head and the fixed support have again been omitted. The chip comprises a first contact pad 611, and the mounting surface comprises a second contact pad 621. A solder bump 651 has been placed between 611 and 621. The resistance of the solder bump 651 depends on the gap 63 between the chip 61 and the mounting surface in the measurement location 64 where this bump is located. First and second contact pads may be connected to a measurement arrangement which can measure the resistance between them, and this resistance measurement can be used as an indicator of the height of the gap 63.

It may in practice be difficult to measure the resistance of a single bump 651 with high accuracy. The accuracy may be improved by connecting multiple bumps in series and measuring the resistance between the two ends of this series. FIG. 6a illustrates a system where the chip 61 comprises multiple first contact pads 611-613, and the mounting surface comprises multiple second contact pads 621-623. Multiple solder bumps 651-655 are connected in series between the first contact pads and the second contact pads, so that the sum of the resistances of all of these solder bumps 651-655 can measured with a measurement arrangement which can measure the resistance between the first and last contact pads in the series. All solder bumps and contact pads are located within a measurement location 64. A linear arrangement of the series in the x-direction is illustrated in FIG. 6b, but the bumps and contact pads which form the series may for example be arranged in a more compact pattern, for example a square, in the xy-plane. The measured resistance will then be proportional to the average gap at the measurement location 64. The tilt angle can be determined by repeating the same measurement on bumps and contact pads in multiple measurement locations.

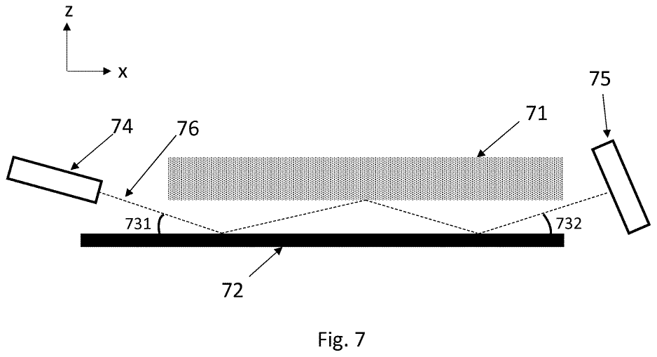

Another way to measure the tilt angle directly measuring the tilt angle is illustrated in FIG. 7. In this embodiment, measuring the angle between the surface of the chip 71 and the mounting surface 72 may comprise illuminating the gap between the chip and the mounting surface with a radiation source 74 which emits a beam 76 of electromagnetic radiation into the gap between the chip and the mounting surface at a nonzero entrance angle 731 in relation to the mounting surface. The beam is reflected between the chip 71 and the mounting surface 72. Measuring the tilt angle further comprises measuring the exit angle 732 of the beam in relation to the mounting surface.

The wavelength of the electromagnetic radiation may in this case lie in the visible or ultraviolet range. The wavelength may be one or more orders of magnitude smaller than the expected gap between the chip and the mounting surface. The wavelengths for example in the range 10 nm-800 nm, or in the range 400 nm-800 nm, or in the range 10 nm-400 nm. The entrance angle 731 may for example be in the range 0.1-10 degrees, or in the range 0.1-5 degrees, or in the range 0.1-0.5 degrees. However, the optimal entrance angle will depend both on the size of the chip and on the desired gap between the chip and the mounting surface. Entrance angles which fall outside of the ranges mentioned above could therefore also be used in some applications.

In both FIGS. 5a-5b and 7, the measurement arrangement comprises a radiation source and a radiation detector, and the radiation source is configured to illuminate the gap between the chip and the mounting surface with electromagnetic radiation and the radiation detector is configured to measure the electromagnetic radiation which exits the gap.

In FIGS. 5a-5b, the radiation source is configured to illuminate the gap between the chip and the mounting surface with electromagnetic radiation so that said electromagnetic radiation is diffracted at the gap, and the radiation detector is configured to measure the diffracted electromagnetic radiation. In FIG. 7 the radiation source illuminates the gap between the chip and the mounting surface so that said electromagnetic radiation is reflected between the chip and the mounting surface, and the radiation detector is configured to measure the exit angle of the reflected electromagnetic radiation.

1. A method for attaching a chip on a mounting surface in a flip-chip bonding system, comprising
pressing the chip toward the mounting surface by applying pressure on the chip, wherein said pressure has a spatial distribution across the surface of the chip,
measuring a tilt angle between the chip and the mounting surface while the chip is being pressed toward the mounting surface,
comparing the measured tilt angle to a predetermined threshold and, if the measured tilt angle differs from the threshold, adjusting the tilt angle by adjusting the pressure distribution while the chip is being pressed toward the mounting surface.

2. A method according to claim 1, wherein measuring the tilt angle comprises measuring a gap between the chip and the mounting surface in two or more measurement locations.

3. A method according to claim 2, wherein the chip is grasped by a movable bonding head, and the bonding head comprises a first transparent section in each of the two or more measurement locations, through which the chip can be illuminated, and the bonding head further comprises a second transparent section in each of the two or more measurement locations, through which the mounting surface can be illuminated, and measuring the gap between the surface of the chip and the mounting surface in each of the two or more measurement locations comprises simultaneously illuminating the chip through the first transparent section and the mounting surface through the second transparent section and measuring an interferometry pattern between electromagnetic radiation reflected through the first transparent section from the chip and electromagnetic radiation reflected through the second transparent section from the mounting surface.

4. A method according to claim 3, wherein the electromagnetic radiation which reaches the chip through the first transparent section is reflected back to the first transparent section from a top surface of the chip which is closer to the bonding head.

5. A method according to claim 3, wherein the electromagnetic radiation which reaches the chip through the first transparent section is reflected back to the first transparent section from a bottom surface of the chip which is further away from the bonding head.

6. A method according to claim 2, wherein the mounting surface comprises a superconducting circuit, and the superconducting circuit comprises a co-planar waveguide resonator in each of the two or more measurement locations, and measuring the gap between the surface of the chip and the mounting surface in each of the two or more measurement locations comprises measuring a resonance frequency of the co-planar waveguide resonator in each of the two or more measurement locations.

7. A method according to claim 2, wherein the chip comprises a superconducting circuit, and the superconducting circuit comprises a co-planar waveguide resonator in each of the two or more measurement locations, and measuring the gap between the surface of the chip and the mounting surface in each of the two or more measurement locations comprises measuring a resonance frequency of the co-planar waveguide resonator in each of the two or more measurement locations.

8. A method according to claim 2, wherein measuring the gap between the surface of the chip and the mounting surface in each of the two or more measurement locations comprises illuminating said gap at each of the two or more measurement locations with a light source which emits electromagnetic radiation into the gap so that said electromagnetic radiation is diffracted at the gap, and measuring the gap further comprises measuring the diffracted electromagnetic radiation with a radiation detector.

9. A method according to claim 1, wherein the chip comprises a bottom surface with one or more first contact pads, and the mounting surface comprises one or more second contact pads, and the one or more first contact pads are aligned with the one or more second contact pads when the chip is positioned above the mounting surface, and the method comprises placing electrically conductive solder bumps on the one or more first contact pads and/or on the one or more second contact pads before pressing the chip toward the mounting surface, and measuring the tilt angle between the surface of the chip and the mounting surface comprises measuring a resistance between at least one first contact pad and at least second contact pad which are connected to each other by at least one solder bump.

10. A method according to claim 2, wherein measuring the tilt angle between the surface of the chip and the mounting surface in each of the two or more measurement locations comprises illuminating the gap between the chip and the mounting surface with a radiation source which emits a beam of electromagnetic radiation into the gap between the chip and the mounting surface at a nonzero entrance angle in relation to the mounting surface, so that said beam is reflected between the chip and the mounting surface, and measuring the tilt angle further comprises measuring an exit angle of the beam in relation to the mounting surface.

11. A flip-chip bonding apparatus comprising an actuator coupled to a chip and a control unit coupled to the actuator, whereby the control unit is configured to control the actuator so that it presses the chip toward a mounting surface, wherein a pressure applied by the actuator has a spatial pressure distribution across the surface of the chip, wherein the apparatus also comprises a measurement arrangement coupled to the control unit, and the measurement arrangement is configured to measure a tilt angle between the chip and the mounting surface when the actuator presses the chip toward the mounting surface, wherein the control unit is configured to adjust the tilt of the chip by adjusting the pressure distribution based on the measured tilt angle.

12. A flip-chip bonding apparatus according to claim 11, wherein the measurement arrangement comprises a device for measuring a gap between the chip and the mounting surface in two or more measurement locations.

13. A flip-chip bonding apparatus according to claim 12, wherein the apparatus comprises a bonding head configured to grasp the chip, and the bonding head comprises a first transparent section in each of the two or more measurement locations, through which the chip grasped by the bonding head can be illuminated, and the bonding head further comprises a second transparent section in each of the two or more measurement locations, through which the mounting surface held by a fixed support can be illuminated, and the measurement arrangement comprises one or more sources of electromagnetic radiation configured to simultaneously transmit electromagnetic radiation through the first transparent section and second transparent section, and the measurement arrangement comprises an interferometer configured to measure a interferometry pattern between electromagnetic radiation reflected back through the first transparent section and electromagnetic radiation reflected back through the second transparent section.

14. A flip-chip bonding apparatus according to claim 12, wherein the measurement arrangement comprises a radiation source and a radiation detector, and the radiation source is configured to illuminate the gap between the chip and the mounting surface with electromagnetic radiation and the radiation detector is configured to measure the electromagnetic radiation which exits the gap.

15. A method of using a superconducting circuit on a chip or on a mounting surface for measuring a tilt angle between the chip and the mounting surface while the chip is being pressed toward the mounting surface in a flip-chip bonding process, wherein the superconducting circuit comprises a co-planar waveguide resonator in two or more measurement locations where a gap between the chip and the mounting surface is measured, and the use comprises measuring a resonance frequency of each coplanar waveguide resonator.

16. (canceled)
